(19) United States
(12) Patent Application Publication
(10) Pub. No.: US 2006/0213686 A1
(43) Pub. Date: Sep. 28, 2006

(54) Cut Via Structure For And Manufacturing Method Of Connecting Separate Conductors

(76) Inventor: Shin-Hsien Wu, Yangmei Township (TW)

Correspondence Address: LIN & ASSOCIATES INTELLECTUAL PROPERTY, P.O. BOX 2339, SARATOGA, CA, 95070-0339, US

(21) Appl. No.: 11/422,601

(22) Filed: Jun. 7, 2006

Related U.S. Application Data
(62) Division of application No. 11/023,897, filed on Dec. 28, 2004.

(51) Int. Cl. H05K 1/11

(52) U.S. Cl. 174/262; 174/264

(57) ABSTRACT

A cut via structure for and a manufacturing method of connecting separate conductors are provided. The cut via structure is electrically connected to a substrate. It includes at least two separate conductors. These conductors form a central-hollow via structure. Alternatively, the central hole can be filled with desired materials (central-filling structure). The conductors are separated by gaps among them. The gaps are formed in a vertically or slantly cut direction with respect to the substrate surface. The cut via structure further comprises a filling layer filled in between the separate conductors. Determined by the material property of the filling layer, the cut via structure can be used as a capacitor or a resistor, or for signal shielding. The cut via structure is made after the formation of a conventional via structure that has no signal shielding effect. This invention has the advantages of low manufacturing cost as well as flexible circuit board design due to its adjustable electrical parameters.

### CROSS-REFERENCES TO RELATED APPLICATIONS

This is a division of U.S. application Ser. No. 11/023,897, filed Dec. 28, 2004.

### FIELD OF THE INVENTION

The present invention generally relates to a via structure and its manufacturing method, and more specifically to a cut via structure which can be used as a capacitor or as a resistor or for signal shielding, and its manufacturing method.

### BACKGROUND OF THE INVENTION

The trend of technological advance of electronic devices and instruments, especially in high frequency communication applications, is high speed, low power consumption, small form factor, and low noise. This technological trend has resulted in many new requirements for designs of printed circuit board (PCB) and high-frequency circuit. In general, high-frequency circuit designs require highly integrated circuit blocks and thus high interconnect density. To meet the demand of increasing interconnect density and reducing interference of noise in high-frequency circuit designs, multilayer PCBs must be adopted. And, stringent technical specifications of interconnected PCB layers, such as crosstalk and impedance matching, are also needed to meet the performance requirements.

Via holes in a PCB layer are used for mounting and connecting circuit components and for interconnecting multiple PCB layers. Nowadays, individual circuit components mounted on the PCB becomes fewer with increasing use of surface mount device (SMD) packaging. Therefore, the diameters of the via holes that are not connected to any individual circuit component are made very small (usually less than 25 milli-inch).

Practically, via holes have been proposed for use in various applications. According to European patent publication EP1341254, an interconnect system for high-frequency transmission lines was disclosed. The structure of this system consists of two transmission lines that are further comprised of a stripline or microstrip line, two ground patterns, a cut via, an electrode, and a clearance formed between the cut via and the ground patterns. The system provides the two transmission lines with a solid mechanical junction, and also achieves a good impedance matching. However, each stripline or microstrip line requires a whole and separate ground plate, which results in a waste of board area.

FIG. 1A shows an SMD-type capacitor mounted on a conventional substrate. FIG. 1B shows a capacitor embedded in a conventional substrate.

At present, the SMD-type capacitors and resistors are widely adopted in the PCB industry but the embedded-type capacitors and resistors are becoming more and more popular. As shown in FIG. 1A, trace 102 is the only conducting path of the electrical signal from integrated circuit (IC) 101 to SMD-type capacitor 103. In this case, SMD-type capacitor 103 occupies plenty of board area because of its large size. Referring to FIG. 1B, the electrical signal to be transmitted from integrated circuit (IC) 101 to embedded-type capacitor 106 must go through trace 102 and trace 105. Therefore, the conducting path for embedded-type substrate is longer than that for SMD-type substrate. Besides, the embedded-type capacitor is often formed by bonding a layer of capacitor-forming material onto substrate 108 using conventional lamination process. However, embedded type components do not occupy board surface area. These two schemes have their own pros and cons, respectively.

According to Taiwan Patent 525417, a coaxial via 200 is proposed, as shown in FIG. 2. The coaxial via 200 comprises an outer cylindrical-shell conductor 201, an inner cylindrical-shell conductor 202, and an insulating layer 203 in between. The coaxial via 200 can be used as a capacitor, a resistor, or for signal shielding. However, the coaxial structure makes the coaxial via 200 behave like an inductor, and thus results in significant signal transmit loss at high frequency due to its high value of impedance. This will be demonstrated thereafter. Another Taiwan Patent 589729 disclosed a substrate with signal shielding vias which are usually formed by plating a layer of different material on the via wall, as shown in FIG. 3. The similar type of coaxial structure will lead to same problem of signal transmit loss at high frequency transmission.

Basically, all the via structures can shorten the electrical conduction path and reduce the complexity of circuit board design. A practical design of via structure is supposed to reduce manufacturing cost and to increase flexibility of circuit board design with adjustable electrical parameters (e.g., impedance, resistance, and capacitance).

### SUMMARY OF THE INVENTION

The present invention has been made to lower the manufacturing cost, to reduce the complexity and to increase the flexibility of circuit board design by the use of a practical via structure. Its primary objective is to provide a cut via structure.

The cut via structure is electrically connected to a substrate. It comprises at least two separate conductors. These conductors form a central-hollow or central-filling via structure, and are separated by at least one gap among them. The gaps are formed in a vertically or slantly cut direction with respect to the substrate surface.

According to this invention, the cut via structure further comprises a filling layer filled in between the separate conductors. Electrical characteristics of the cut via structure are determined by the material property of the filling layer. The cut via structure can be used as a capacitor if the filling material is a capacitor-forming material and has a dielectric constant of greater than 1. The cut via structure can also be used as a resistor if the filling material is a resistor-forming material. Alternatively, anyone of the conductors in the cut via structure can be connected to the ground potential of the circuitry to produce signal shielding/control effect of a transmission line.

In the first and the second embodiments of this invention, the separate conductors form a central-hollow via structure. In the third and the fourth embodiments of this invention, the separate conductors form a central-filling via structure.

Another objective of this invention is to provide a manufacturing method for the cut via structure. This method comprises the following steps: (a) prepare a substrate that comprises either a central-hollow or a central-filling via structure. For the central-hollow via structure, a conducting layer is formed on the wall of the hole by deposition, electrolytical plating, etc. For the central-filling via structure, the central hole is filled with a conducting material by deposition, electrolytical plating, etc. (b) cut through the conductor vertically or slantly with respect to the substrate surface to form at least one gap and at least two separate conductors. (c) adjust and optimize the distances of the gaps based on the values of some predetermined parameters.

According to the invention, the cutting methods in step (b) include laser trimming, knife cutting, and tool cutting, etc. The predetermined parameters in step (c) include distances of gaps, electrical characteristics of separate conductors, etc.

According to the present invention, the cut via structure is made after the formation of a conventional via structure that has no signal shielding effect. It has the advantages of: (1) low manufacturing cost, (2) adjustable electrical characteristics (e.g., inductance, resistance, and capacitance), (3) plural capacitors and/or resistors and even signal shielding effect, which can be produced in a single via structure, (4) various via structures with different electrical characteristics (e.g., capacitance, resistance, and signal shielding effect) optimized for different applications, which can be produced on a single substrate, (5) embedded-type capacitors produced by filling the vias with a capacitor-forming material instead of bonding a whole layer of capacitor-forming material onto the substrate (e.g., PCB or any kind of substrate used for carrying integrated circuits components) using a conventional lamination process.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1A shows an SMD-type capacitor mounted on a conventional substrate.

FIG. 1B shows an embedded-type capacitor in a conventional substrate.

FIG. 2 shows a conventional via structure that consists of two coaxial cylindrical-shell conductors and an insulating layer in between.

FIG. 3 shows a conventional substrate with a signal shielding via structure.

FIG. 4A shows a perspective view of the cut via structure according to the present invention.

FIG. 4B is similar to FIG. 4A except that FIG. 4B has a filling layer filled in between the separate conductors.

FIG. 5A shows a top view of the first embodiment of this invention.

FIG. 5B shows a perspective view of the first embodiment of this invention.

FIG. 5C shows the first embodiment of this invention, in which the cut via structure is located outside a supporting substrate.

FIG. 5D shows an enlarged view of the cut via structure highlighted by dashed line in FIG. 5C.

FIG. 5E shows a perspective view of the second embodiment of this invention, in which a single via structure comprises two separate device components.

FIGS. 6A and 6B show the cross-sectional views of the cut via structures with different shapes of via walls.

FIG. 6C shows a perspective view of the cut via structure with two gaps cutting through a conductor slantly with respect to the substrate surface.

FIGS. 7A and 7B show the top views of the cut via structures containing three and four separate conductors, respectively.

FIG. 8A shows a top view of the third embodiment of this invention.

FIG. 8B shows a perspective view of the third embodiment of this invention.

FIG. 8C shows a perspective view of the fourth embodiment of this invention, in which a single via structure comprises two separate device components.

FIG. 9A illustrates a flow of the manufacturing method according to the present invention.

FIG. 9B shows that a gap filling step is inserted to FIG. 9A.

FIGS. 10A to 10F show perspective views of the major manufacturing steps of this invention.

FIG. 11 shows a substrate comprising an embedded-type capacitor produced by a cut via structure.

FIG. 12 shows a comparison of electrical characteristics of various via structures.

### DETAILED DESCRIPTION OF THE PREFERRED EMBODIMENTS

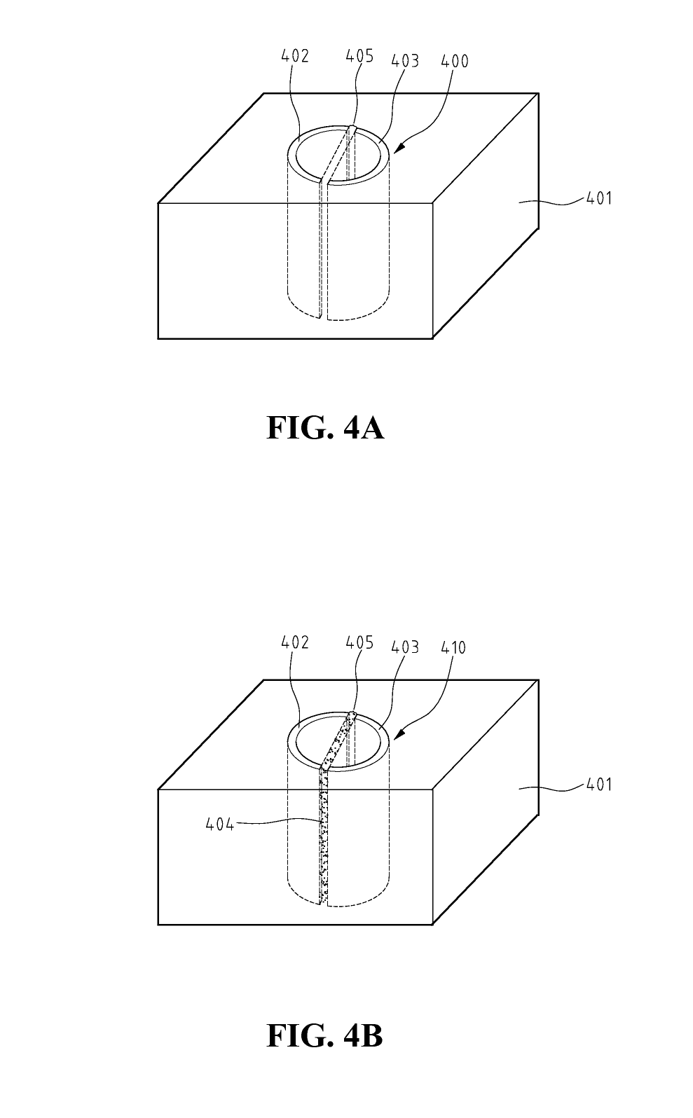

FIG. 4A shows a perspective view of the cut via structure according to the invention. A cut via structure 400 can be formed either inside or outside a substrate 401. The cut via structure 400 is further described in the following for the case that it is formed inside the substrate 401.

Referring to FIG. 4A, the cut via structure 400 of this invention is electrically connected to the substrate 401 and comprises at least two separate conductors 402 and 403. These conductors, at least 402 and 403, form a central-hollow or central-filling via structure and are separated by at least one gap 405 in between. These gaps are formed in a vertically or slantly cut direction with respect to the substrate surface. According to the invention, the cut via structure 400 further comprises a filling layer 404 filled in between the separate conductors 402 and 403, as shown in FIG. 4B.

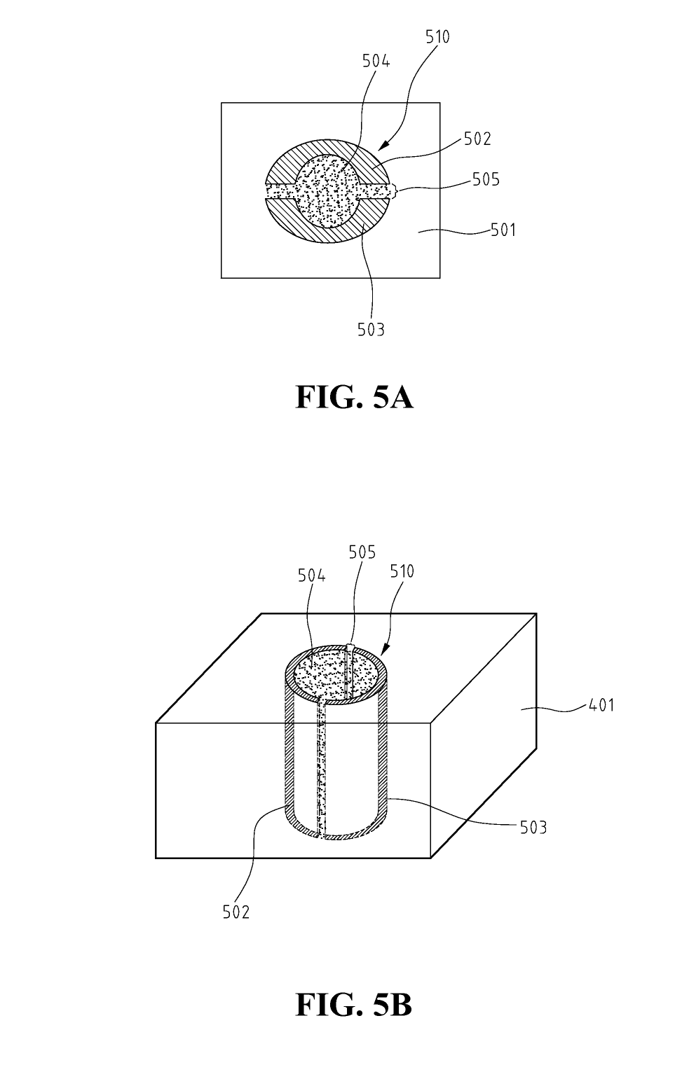

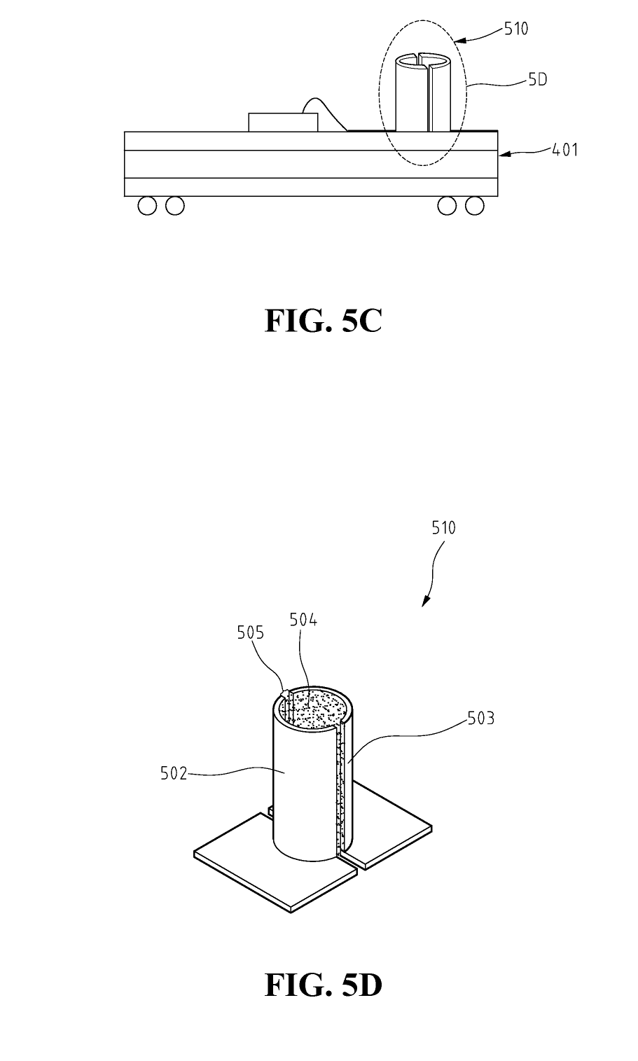

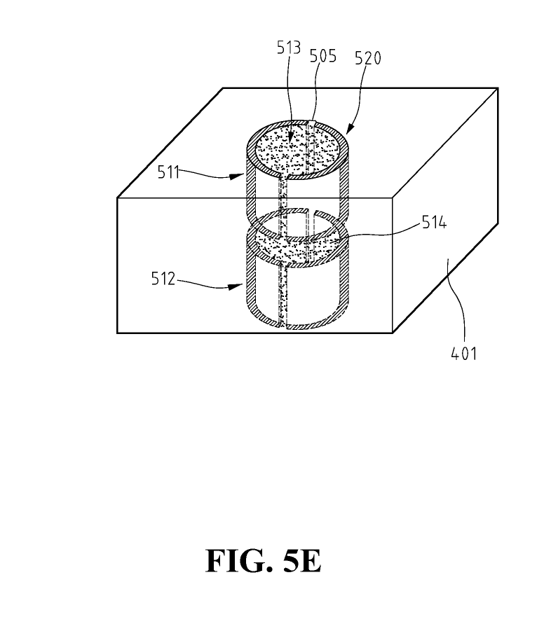

FIG. 5A shows the top view of the first embodiment of the invention. FIG. 5B shows a perspective view of the first embodiment of this invention. FIG. 5C shows the cut via structure of the first embodiment of this invention, in which the cut via structure is located outside a supporting substrate. FIG. 5D shows an enlarged view of the cut via structure highlighted by dashed line in FIG. 5C. FIG. 5E shows a perspective view of the second embodiment of the invention, in which a single via structure comprises two separate device components.

A detailed description of the first and the second embodiments of this invention is provided herein below.

Referring to FIG. 5A, a cut via structure 510 of this invention is electrically connected to a substrate 401 and comprises at least two separate conductors 502, 503 and one filling layer 504. These two separate conductors 502 and 503 form a central-hollow via structure, and are separated by at least two gaps 505 formed in a vertically or slantly cut direction with respect to the substrate surface. The filling layer 504 is a layer of material filled in between the two conductors 502 and 503.

Furthermore, the cut via structure 510 can be formed either inside the substrate 401 (as shown in FIGS. 5A and 5B) or outside the substrate 401 (as shown in FIG. 5C). Wherein, FIG. 5D shows an enlarged 3-dimentional view of the cut via structure highlighted by dashed line in FIG. 5C.

The cut via structure 510 can be used as a capacitor if the filling layer 504 is a capacitor-forming material and has a dielectric constant of greater than 1. Similarly, the cut via structure 510 can also be used as a resistor if the filling layer 504 is a resistor-forming material. Alternatively, anyone of the conductors in the cut via structure can be connected to the ground potential of the circuitry to produce signal shielding effect of a transmission line.

According to this invention, the cut via structure can have a single via with a single device property. The single via can further includes plural device components. As shown in FIG. 5E, a cut via structure 520, comprising two separate cut via units 511 and 512, are formed by cutting through the cut via structure 510 horizontally. The electrical characteristics of the cut via units 511 and 512, which are determined by the material properties of the filling layers 513 and 514, can be different.

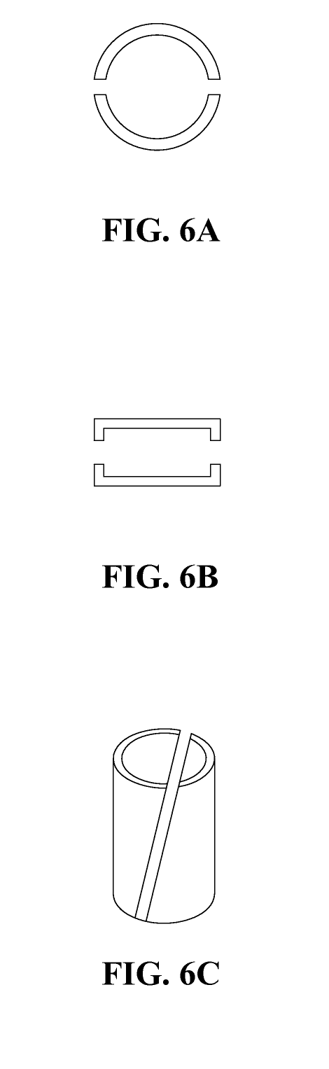

FIGS. 6A and 6B show the cross-sectional views of the cut via structures with different shapes of via walls. FIG. 6C shows a perspective view of the cut via structure with two gaps cutting through a conductor slantly with respect to the substrate surface.

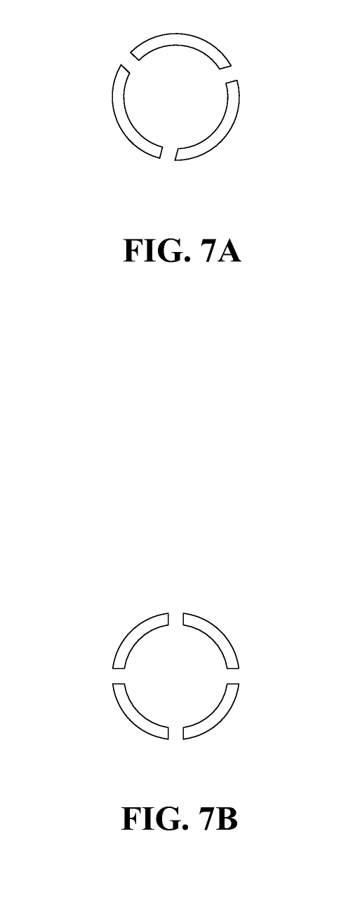

FIGS. 7A and 7B show the top views of the cut via structures with three and four separate conductors, respectively.

The horizontal cross section of the cut via structure can be arbitrary shape, e.g., circular shape (shown in FIG. 6A) or oval shape (shown in FIG. 5A) or rectangular shape (shown in FIG. 6B). The gaps between the separate conductors of the cut via structure are formed by either cutting through a vertical direction (shown in FIG. 5B) or a slant direction (shown in FIG. 6C) with respect to the substrate surface.

Furthermore, the substrate 401 can be a PCB board or a packaging substrate for integrated circuits chip or a connector or a heat sink or any commonly used chip carrier. The cut via structure of a single via can be formed by two or more separate conductors, such as three conductors (shown in FIG. 7A) or four conductors (shown in FIG. 7B). And, the conductors can be made of any conducting material, such as copper, gold, silver, platinum, etc.

A detailed description of the third and the fourth embodiments of this invention is provided herein below for the case that the cut via structure is formed inside the substrate 401.

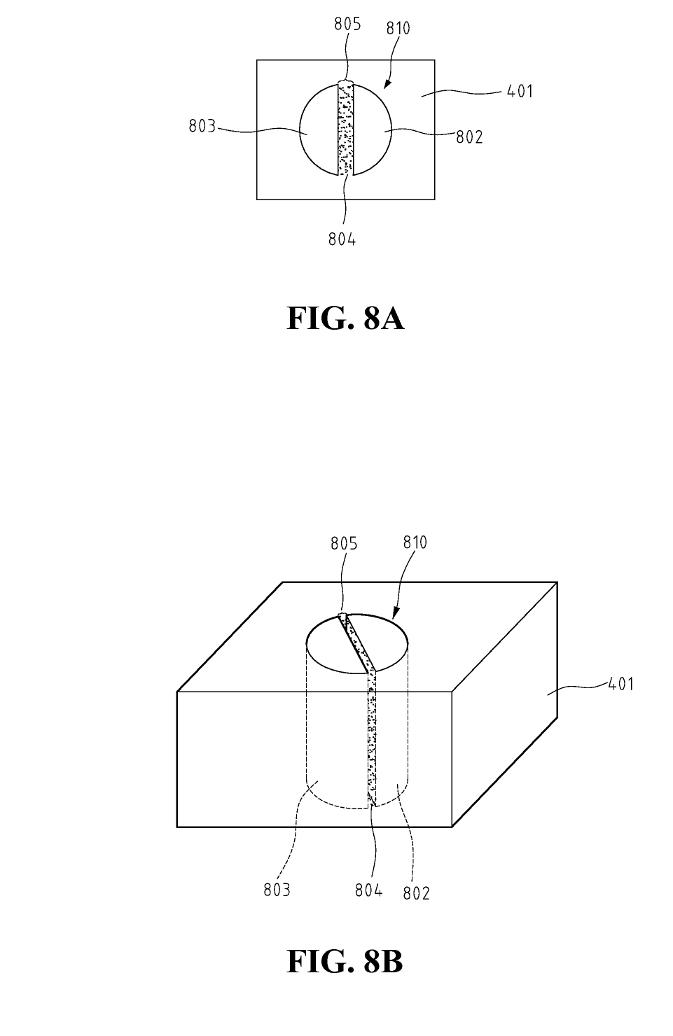

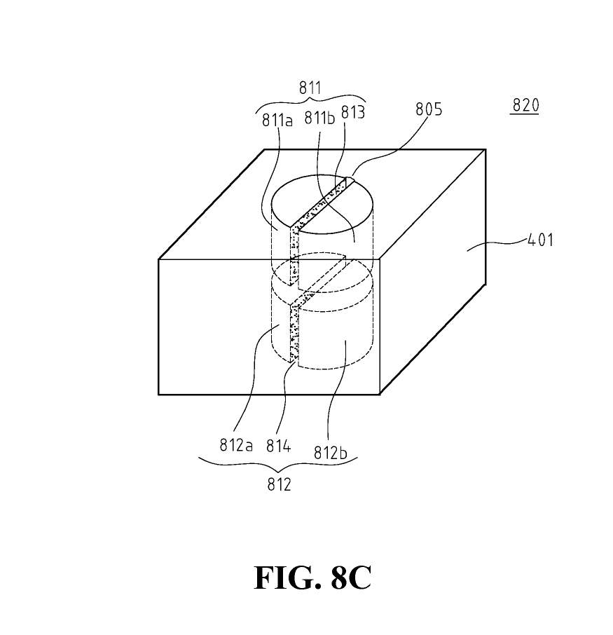

FIG. 8A shows a top view of the third embodiment of this invention. FIG. 8B shows a perspective view of the third embodiment of this invention. FIG. 8C shows a perspective view of the fourth embodiment of this invention, in which a single via structure comprises two separate device components.

Referring to FIGS. 8A and 8B, the cut via structure 810 is electrically connected to the substrate 401 and comprises at least two separate conductors 802, 803 and one filling layer 804. These two separate conductors 802 and 803 form a central-filling via structure, and are separated by at least one gap 805 formed in a vertically or slantly cut direction with respect to the substrate surface. The filling layer 804 is a layer of material filled in between two conductors 802 and 803. As shown in FIG. 8C, a cut via structure 820, comprising two separate cut via units 811 and 812, are formed by cutting through the cut via structure 810 horizontally. The electrical characteristics of the cut via units 811 and 812, which are determined by the material properties of the filling layers 813 and 814, can be different.

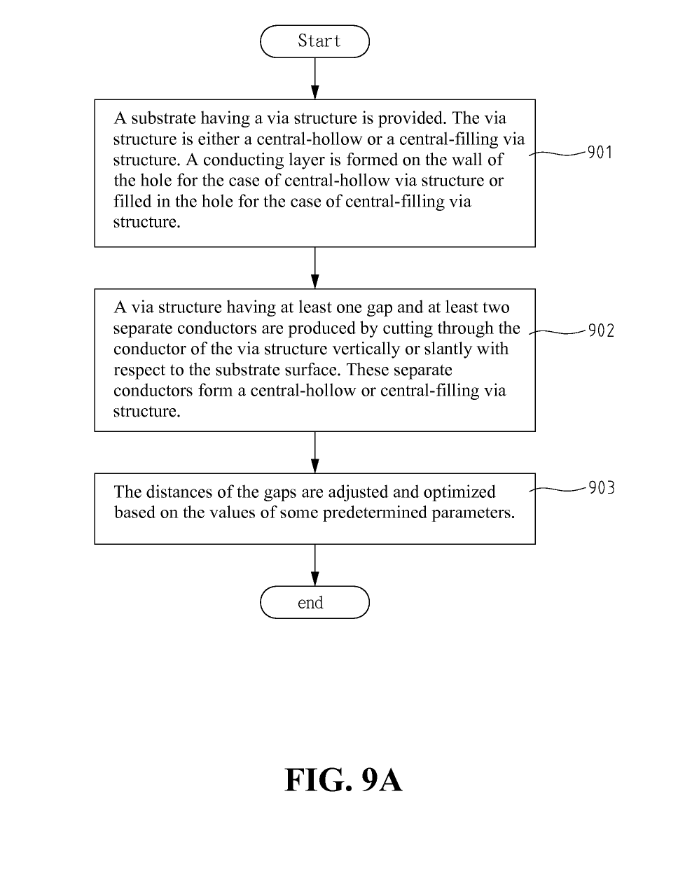

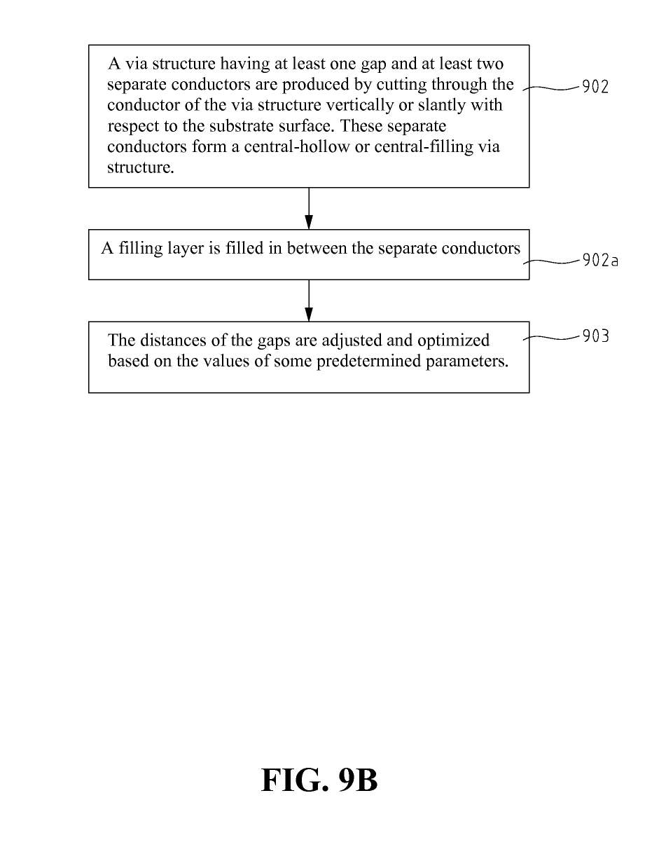

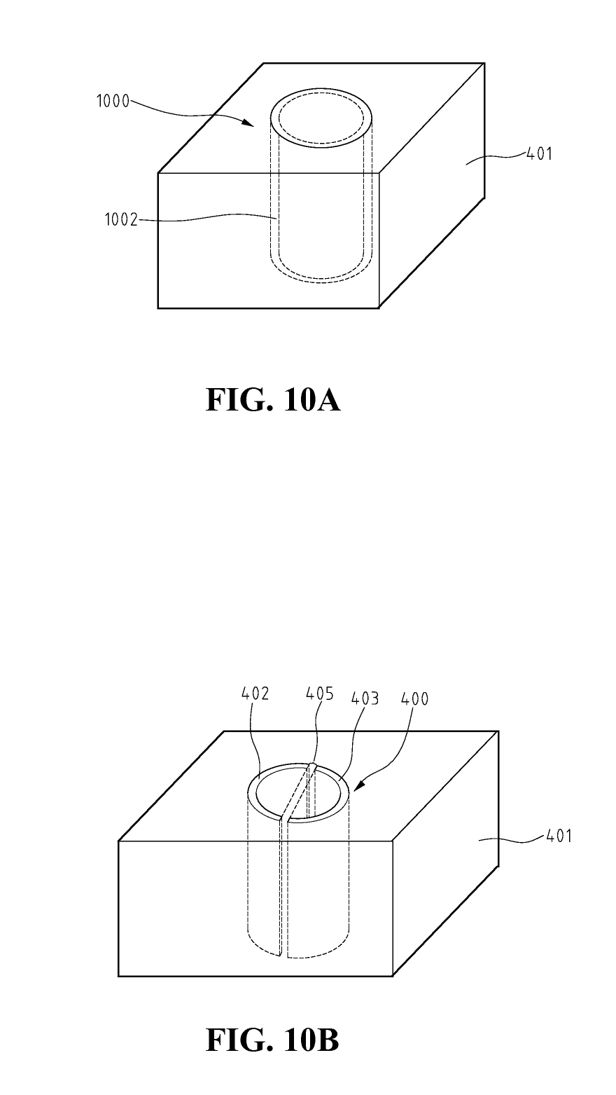

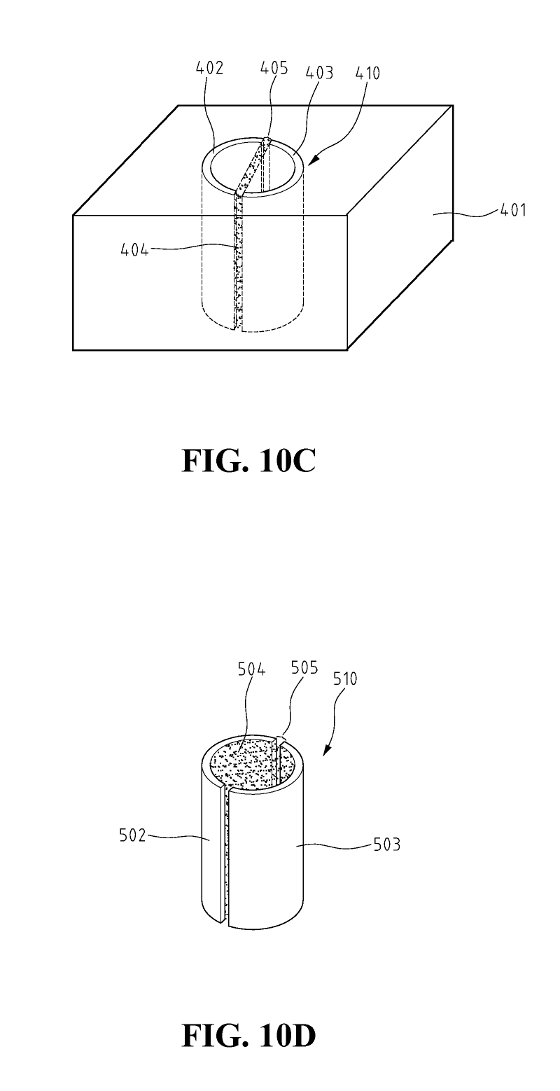

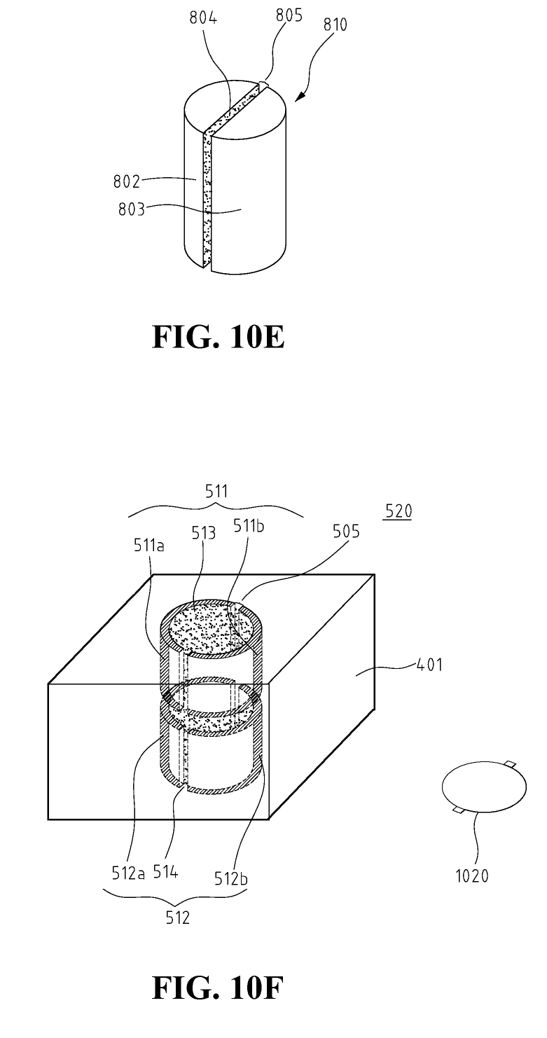

FIG. 9A illustrates a flow of the manufacturing method according to this invention. FIGS. 10A to 10F show perspective views of the major manufacturing steps of this invention.

Referring to FIG. 9A and FIGS. 10A to 10F, a detailed description of the manufacturing method of this invention is provided herein below.

Firstly, a substrate 401 having a via structure 1000 is provided, as shown in step 901. The via structure 1000 is either a central-hollow or a central-filling via structure. As shown in FIG. 10A, a conducting layer 1002 is formed on the wall of the hole for the case of central-hollow via structure or filled in the hole for the case of central-filling via structure. This can be done by deposition, electrolytical plating, etc.

Secondly, a via structure 400 having at least one gap 405 and at least two separate conductors 402 and 403 are produced by cutting through the conductor 1002 of the via structure 1000 vertically or slantly with respect to the substrate surface, as shown in step 902. These separate conductors form a central-hollow or central-filling via structure. FIG. 10B illustrates that a gap 405 is formed by a vertical cut.

Lastly, the distances of the gaps are adjusted and optimized based on the values of some predetermined parameters, as shown in step 903. This is to verify that if the impedance values resulted from the distances thus produced can match with the predetermined values or not. These predetermined parameters include distances of gaps among separate conductors and electrical characteristics of the separate conductors. Alternatively, anyone of the conductors in the cut via structure can be connected to the ground potential of the circuitry to produce signal shielding/control effect of a transmission line.

Besides, a gap filling step 902a (as shown in FIG. 9B) can be inserted after step 902, in which a filling layer 404 is filled in between the separate conductors 402 and 403. Hereat, the material used for filling layer 404 is determined by the desired electrical characteristics of the via structure, as shown in FIG. 10C.

In step 903, the predetermined parameters include distances of gaps 405 among separate conductors, electrical characteristics of the separate conductors, and dielectric constant and resistance of the filling layer 404. Based on the values of these parameters, the distances of the gaps are adjusted and optimized. This is to verify if capacitance, resistance, and impedance values resulted from the distances produced after cutting and then filling of the filling layer 404 can match with the predetermined values or not. Wherein the capacitance value is proportional to the dielectric constant of the filling layer and the area of the cross section of the conductor. The capacitance value is inversely proportional to the distance of the gap between the conductors. The resistance value is proportional to the resistance and length of the filling layer but is inversely proportional to the area of the cross section of the filling layer.

After step 903, a stand-alone cut via structure 510 or 810 is produced by baking via structure 410 and removing substrate 401, as shown in FIGS. 10D and 10E. Wherein FIG. 10D shows a central-hollow cut via structure 510 with two gaps. FIG. 10E shows a central-filling cut via structure 810 with one gap. Substrate 401 can be removed by chemical etching.

It's worth to mention that the cutting methods in step 902 include laser trimming, knife cutting, and tool cutting, etc. Wherein the laser cutting method can only create a single via structure with a single device characteristic. However, the knife and tool cutting methods can accommodate special designs and generate a single via structure that has plural device characteristics. As shown in FIG. 10F, a via structure 520, comprising cut via units 511 and 512, are formed by a vertical cut and a horizontal cut with a special knife 1020 through a central-hollow via structure 1000. Wherein the cut via unit 511 comprises conductors 511a and 511b, and a filling layer 513. The cut via unit 512 comprises conductors 512a and 512b, and a filling layer 514. Electrical characteristics of these two units are dependent on the material properties of the filling layers 513 and 514, respectively. For example, they can be a capacitor and a resistor, or a capacitor and a signal shielding device, or two capacitors with different capacitance values.

As shown in FIG. 8C, a via structure 820, comprising cut via units 811 and 812, are formed by a vertical cut and a horizontal cut with a special knife or tool through a central-filling via structure 1000. Wherein the cut via unit 811 comprises conductors 811a and 811b, and a filling layer 813. The cut via unit 812 comprises conductors 812a and 812b, and a filling layer 814. Electrical characteristics of these two units are dependent on the material properties of the filling layers 813 and 814, respectively.

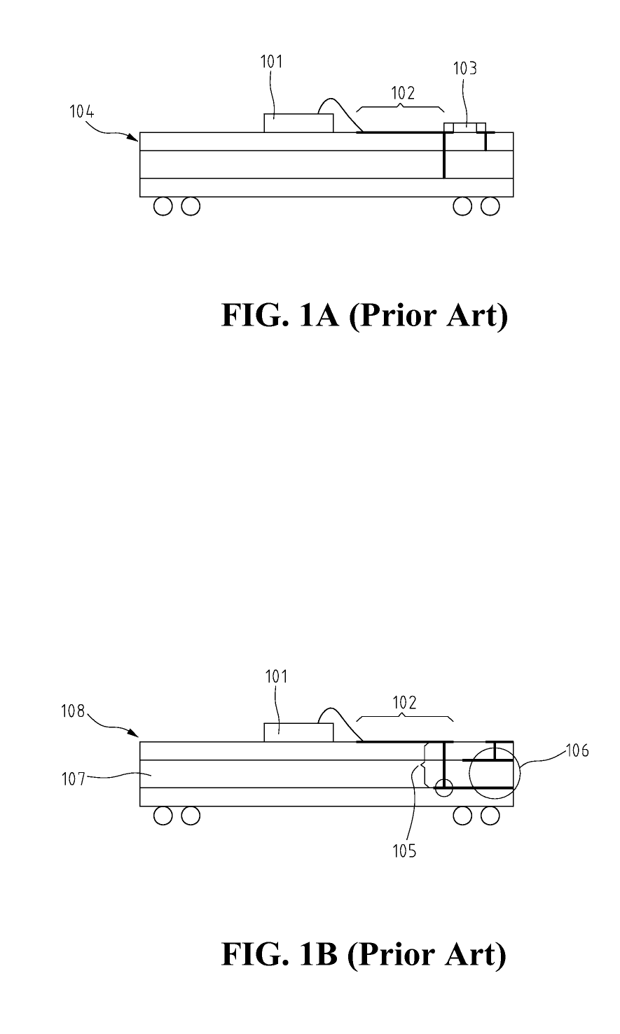

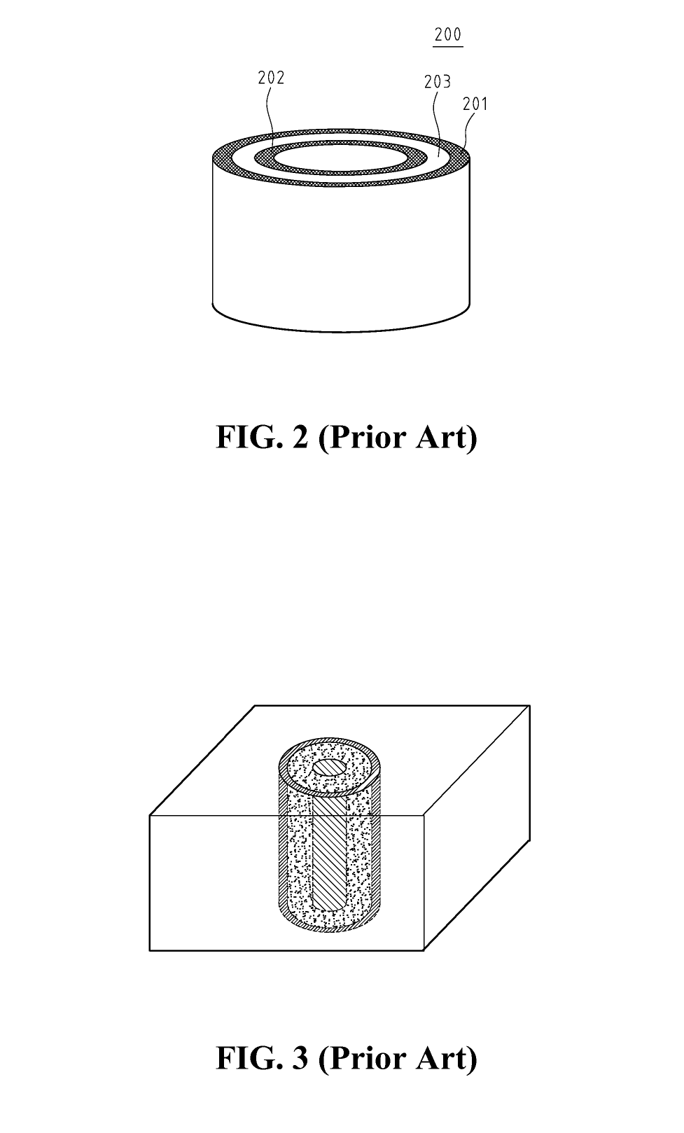

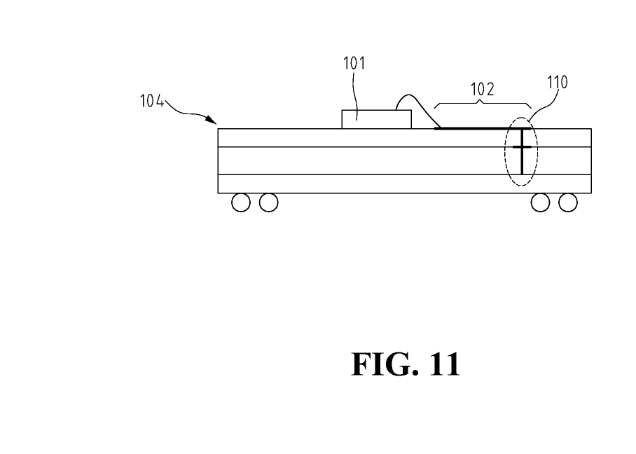

FIG. 11 shows a substrate comprising an embedded-type capacitor produced by a cut via structure (herein below will be called as via capacitor). Comparing FIG. 11 with FIGS. 1A and 1B, it can be seen that trace 102 is the only conducting path of the electrical signal from integrated circuit (IC) 101 to via capacitor 110. This conducting path has the same shortest distance as that in FIG. 1A but it doesn't occupy plenty of board area. Besides, the via capacitor 110 is produced by filling the via with a capacitor-forming material to form an embedded-type capacitor instead of bonding a whole layer of capacitor-forming material 107 onto the substrate 108 using a conventional lamination process.

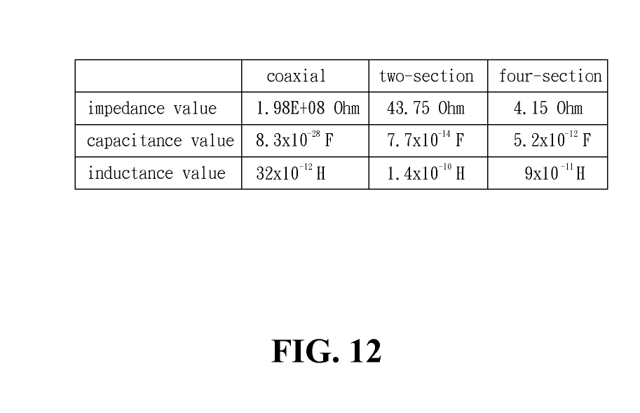

FIG. 12 shows a comparison of electrical characteristics of various via structures, in which impedance, capacitance, and resistance values are compared for a conventional coaxial via structure, a two-section cut via structure (consists of two separate conductors as shown in FIG. 5A) and a four-section cut via structure (consists of four separate conductors as shown in FIG. 7B). The measurement was performed at a frequency of 1 GHz on 576-μm long via structures with a same diameter of 200 μm. The filling layer has a magnetic permeability of 1 and a dielectric constant of 4.3. Wherein the coaxial via structure has a very high impedance value and a large inductance/capacitance (L/C) ratio, which means it behaves like an inductor. The two-section cut via structure has an impedance value close to 50 ohm required for a transmission line. Therefore, it can be used as a signal shielding via. The four-section cut via structure has the largest capacitance value and the smallest impedance value among the three via structures, which means it behaves like a capacitor.

Furthermore, the cut via structure of this invention is made after formation of a conventional via structure that has no signal shielding effect. It has the advantages of: (1) low manufacturing cost and (2) adjustable electrical characteristics. The distances of gaps can be adjusted and optimized to meet desired electrical characteristics based on material properties of filling layer, predetermined impedance values, predetermined capacitance values, and predetermined resistance values. Therefore, plural values of impedance or capacitance or resistance can be produced in a single substrate.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A cut via structure electrically connected to a substrate, said via structure comprises at least two separate conductors to form a central filling via structure, and at least one gap is formed in said central filling via structure by a vertical or slant cut with respect to the surface of said substrate.

2. The cut via structure as claimed in claim 1, wherein said central filling via structure comprises a filling layer filled in among said separate conductors.

3. The cut via structure as claimed in claim 2, wherein said filling layer is chosen from the group of resistor-forming material, insulating material, and capacitor-forming material with a dielectric constant of greater than 1.

4. The cut via structure as claimed in claim 1, wherein said central filling via structure is located outside said substrate.

5. The cut via structure as claimed in claim 1, wherein said central filling via structure is further cut horizontally to form plural cut via units.

6. The cut via structure as claimed in claim 1, wherein said separate conductors comprise at least a material selected from the group consisting of copper, gold, silver, and platinum.

7. The cut via structure as claimed in claim 1, wherein said substrate includes a printed circuit board, a packaging substrate for integrated circuits chip, a connector, a heat sink, and a chip carrier.
